(19) United States
(12) Patent Application Publication
(10) Pub. No.: US 2026/0078487 A1
(43) Pub. Date: Mar. 19, 2026

(54) RESERVOIR-BASED PRECURSOR DELIVERY FOR STABLE AND RAPID FLOW TRANSITIONS IN A PLASMA-ENHANCED ALD PROCESS

(71) Applicant: Applied Materials, Inc., Santa Clara, CA (US)

(72) Inventors: Diwakar N. KEDLAYA, San Jose, CA (US); Shashank SHARMA, Fremont, CA (US); Manjunathagoud BAGAVAD, Bengaluru (IN); Supriya GHOSH, San Jose, CA (US); Susmit SINGHA ROY, Campbell, CA (US); Udit Suryakant KOTAGI, Singapore (SG); Priya CHOUHAN, Fremont, CA (US); Manjunath Veerappa CHOBARI PATIL, Bangalore (IN); Rupankar CHOUDHURY, Bangalore (IN); Sumanth Kurudi GURURAJ, Hospet (IN)

(21) Appl. No.: 19/328,035

(22) Filed: Sep. 12, 2025

Related U.S. Application Data
(60) Provisional application No. 63/696,055, filed on Sep. 18, 2024.

(51) Int. Cl. C23C 16/455

(52) U.S. Cl. CPC C23C 16/45544; C23C 16/45561

(57) ABSTRACT

Embodiments of the present disclosure relate to devices and methods related to gas reservoirs for fast delivery of gases to a processing chamber for processing of a substrate. The gas reservoir includes a first surface and a second surface, the first surface defining a length of the gas reservoir, and the second surface defining a height of the gas reservoir; a plurality of compartments, each compartment operable to hold a gas, and at least two compartments include heating capabilities, a splitter where the splitter is disposed below the plurality of compartments and the splitter is coupled to a gas panel and a valve block, a plurality of gas panel gas lines, and a plurality of gas reservoir gas lines.

### CROSS-REFERENCE TO RELATED APPLICATION

This application claims the benefit of U.S. Provisional Patent Application No. 63/696,055, filed Sep. 18, 2024, which is incorporated by reference herein in its entirety.

### BACKGROUND

### Field

Embodiments of the present disclosure generally relate to devices and methods used in semiconductor processing. More specifically, embodiments described herein relate to gas reservoirs for fast delivery of gases to a processing chamber for processing of a substrate.

### Description of the Related Art

Semiconductor substrates are processed for a wide variety of applications, including the fabrication of integrated devices and microdevices. Operations (e.g., plasma-enhanced advanced layer deposition) can involve a multitude of gases (e.g., process gases, reactive gases, carrier gases, purge cases or any other gas required during semiconductor processing). These gases may need to be vaporized or stabilized before introduction into a processing chamber.

Current techniques do not allow for quick pulsing of different gases during deposition processes (e.g., CVD or ALD), inhibition processes, substrate treatments, etch processes or continuous etch processes. As a result, the amount of time needed for vaporization and stabilization can cause processing delays, reduced throughput, and high operational costs.

Therefore, there is a need for an improved device that allows for rapid and stable flow of gases into a processing chamber.

### SUMMARY

Embodiments of the present disclosure generally relate to devices and methods used in semiconductor processing. More specifically, embodiments described herein relate to gas reservoirs for fast delivery of gases to a processing chamber for processing of a substrate.

In one embodiment, a gas reservoir is provided. The gas reservoir includes a first surface and a second surface, the first surface defining a length of the gas reservoir, and the second surface defining a height of the gas reservoir; a plurality of compartments, each compartment operable to hold a gas, and at least two compartments include heating capabilities, a splitter where the splitter is disposed below the plurality of compartments and the splitter is coupled to a gas panel and a valve block, a plurality of gas panel gas lines, and a plurality of gas reservoir gas lines.

In another embodiment, a processing system is provided. The processing system includes a gas panel, a gas reservoir where the gas reservoir includes a plurality of compartments, each compartment operable to hold a gas, a plurality of gas panel gas lines, and a plurality of gas reservoir gas lines, a plurality of valve blocks, each valve block includes a plurality of valve block gas lines, and a first processing chamber and a second processing chamber, wherein each of the first processing chamber and the second processing chamber is positioned about 24 inches or less from the gas panel, each of the first processing chamber and the second processing chamber includes a processing volume at least partially defined by a chamber body, a substrate support, and an injector operable to inject a gas into the processing volume.

In yet another embodiment, a method for using a gas reservoir in a processing system is provided. The method includes flowing a first gas from a gas panel to a first compartment of a gas reservoir, the gas reservoir including a plurality of compartments, holding the first gas in the first compartment in the gas reservoir, regulating a pressure of the first gas in the first compartment, flowing the first gas from the first compartment in the gas reservoir to a plurality of valve blocks, and flowing the first gas from the plurality of valve block to a plurality of processing chambers.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic cross-sectional view of two processing chambers and a gas reservoir, according to one or more embodiments.

FIG. 2A is a schematic top view of a processing chamber system including a gas reservoir, according to one or more embodiments.

FIG. 2B is a schematic perspective view of a processing chamber system including a gas reservoir, according to one or more embodiments.

FIG. 3 is a schematic cross-sectional view of a gas reservoir, according to one or more embodiments.

FIG. 4A is a schematic perspective view of a gas reservoir, according to one or more embodiments.

FIG. 4B is a schematic top view of a gas reservoir, according to one or more embodiments.

FIG. 5 is a schematic block diagram view of processing system during a substrate processing method, according to one or more embodiments.

FIGS. 6A-6E are schematic diagrams of a processing system during a substrate processing method, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to devices and methods used in semiconductor processing. More specifically, embodiments described herein relate to gas reservoirs used for fast delivery of gases (e.g., precursor gases) to a processing chamber for processing of a substrate applicable to semiconductor manufacturing. In one or more embodiments, a gas reservoir provides fast and stable delivery of gases to a processing chamber. In at least one embodiment, the processing chamber is a deposition chamber. The deposition process may include any one or more methods known to one of ordinary skill in the art, such as plasma-enhanced atomic layer deposition (PEALD), physical vapor deposition (PVD), chemical vapor deposition (CVD), plasma enhanced chemical vapor deposition (PECVD), and the like.

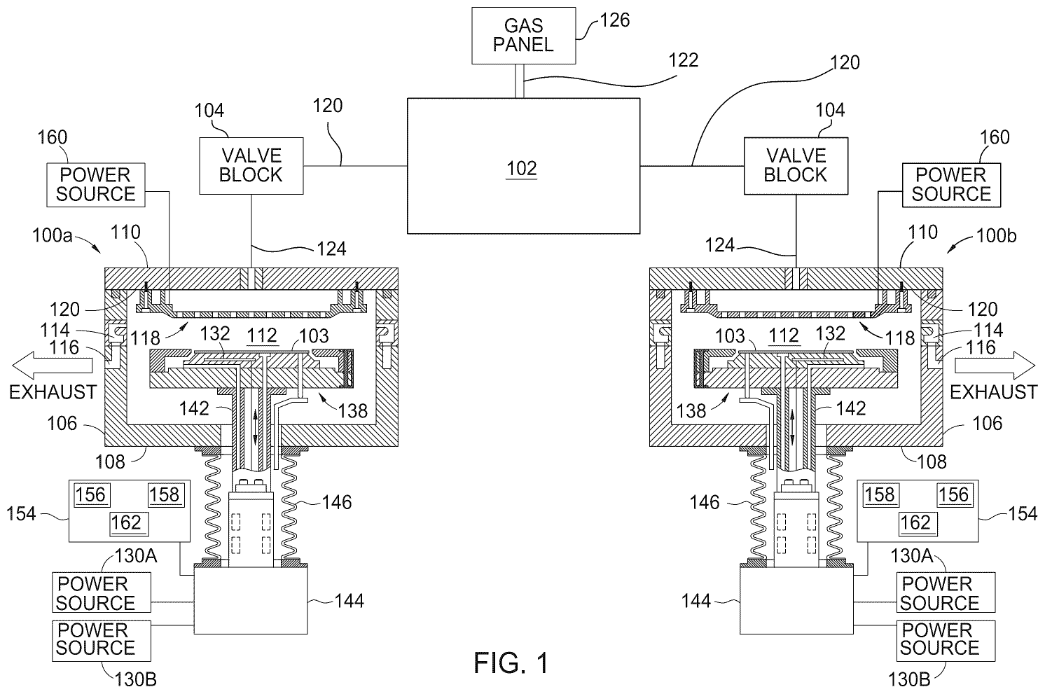

FIG. 1 is a cross-sectional view of two processing chambers 100 (e.g., a first processing chamber 100a and a second processing chamber 100b) and a gas reservoir 102. In various embodiments, the processing chambers 100 may include processing chambers available from Applied Materials, Inc. located in Santa Clara, Calif. For example, processing chambers that may be adapted to perform deposition methods described herein include the PRODUCER® chemical vapor deposition chamber or the TESSERACT® system, available from Applied Materials, Inc. located in Santa Clara, Calif. It is to be understood that the chamber described below is an exemplary embodiment and other chambers, including chambers from other manufacturers, may be used with or modified to match embodiments described herein without diverging from the inventive characteristics described herein.

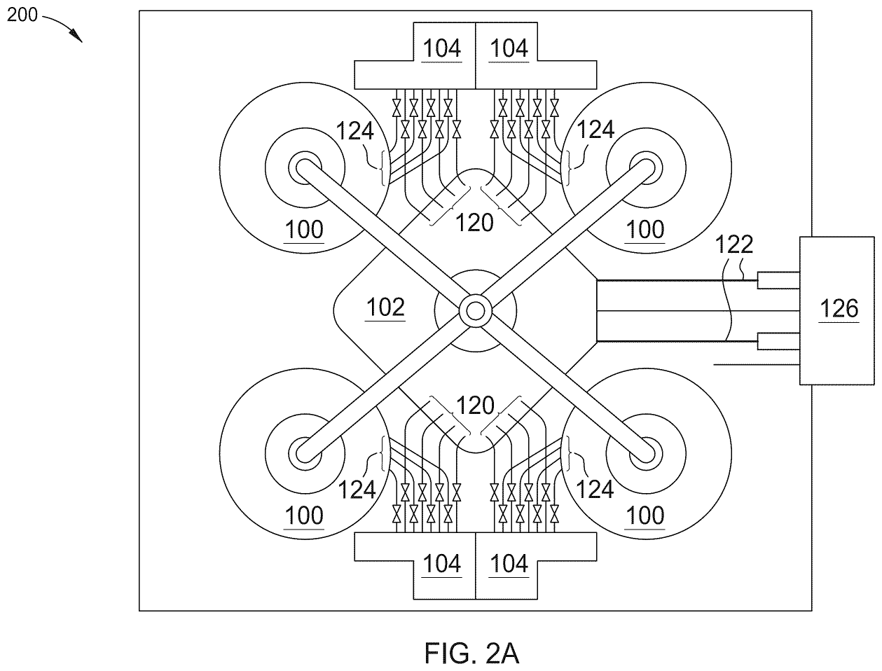

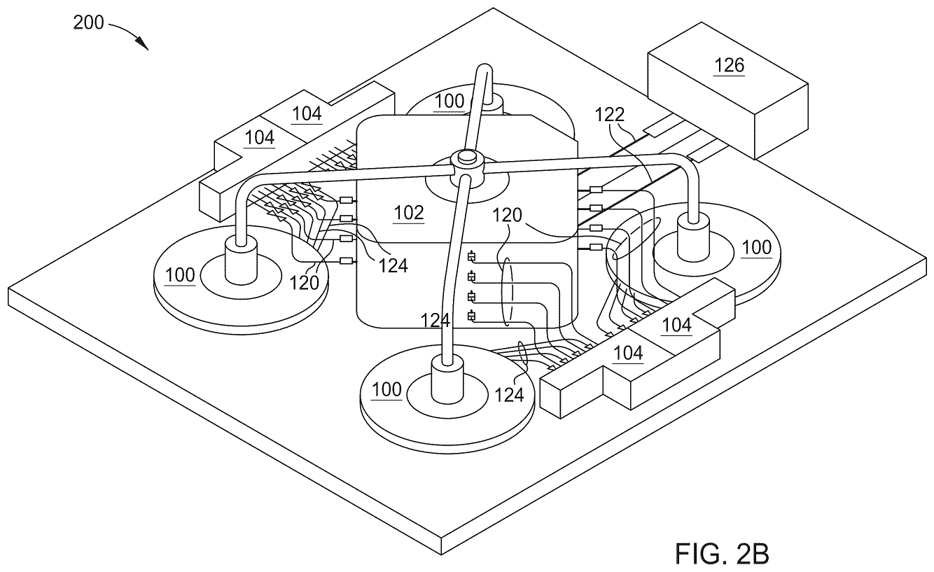

The processing chambers 100 are part of a processing system 200 that includes a gas reservoir 102 and multiple processing chambers (e.g., a first processing chamber 100a and a second processing chamber 100b). In other embodiments, as shown in FIG. 2A, the processing system 200 may include four processing chambers 100. The processing chamber 100 includes walls 106, a bottom 108, and a lid 110 that define a process volume 112. The walls 106 and bottom 108 can be fabricated from a unitary block of aluminum. The process chamber 100 may also include a pumping ring 114 that fluidly couples the process volume 112 to an exhaust port 116 as well as other pumping components (not shown).

A substrate support assembly 138, which may be heated, may be centrally disposed within the processing chambers 100. The substrate support assembly 138 supports a substrate 103 during a deposition process. The substrate support assembly 138 generally is fabricated from aluminum, ceramic or a combination of aluminum and ceramic, and includes at least one bias electrode 132.

A vacuum port may be used to apply a vacuum between the substrate 103 and the substrate support assembly 138 to secure the substrate 103 to the substrate support assembly 138 during the deposition process. The bias electrode 132 may be, for example, disposed in the substrate support assembly 138. The bias electrode 132 may be coupled to a bias power source 130A and 130B to bias the substrate support assembly 138 and substrate 103 positioned thereon to a predetermined bias power level while processing.

The bias power source 130A and 130B can be independently configured to deliver power to the substrate 103 and the substrate support assembly 138 at a variety of frequencies, such as a frequency between about 1 MHz and about 60 MHz. In some embodiments, the bias power source 130A may be configured to deliver power to the substrate 103 at a frequency of about 2 MHz, and the bias power source 130B may be configured to deliver power to the substrate 103 at a frequency of about 13.56 MHz. In other embodiments, the bias power source 130A may be configured to deliver power to the substrate 103 at a frequency of 2 MHz, the bias power source 130B may be configured to deliver power to the substrate 103 at a frequency of 13.56 MHz, and a third power source (not shown) is configured to deliver power to the substrate 103 at a frequency of about 60 MHz. Various permutations of the frequencies described here can be employed without diverging from the embodiments described herein.

Generally, the substrate support assembly 138 is coupled to a stem 142. The stem 142 provides a conduit for electrical leads, vacuum and gas supply lines between the substrate support assembly 138 and other components of the processing chamber 100. Additionally, the stem 142 couples the substrate support assembly 138 to a lift system 144 that moves the substrate support assembly 138 between an elevated position (as shown in FIG. 1) and a lowered position (not shown) to facilitate robotic transfer. Bellows 146 provide a vacuum seal between the process volume 112 and the atmosphere outside the processing chambers 100 while facilitating the movement of the substrate support assembly 138.

The gas reservoir 102 is positioned between the processing chambers 100. As shown in FIG. 1, the gas reservoir 102 is positioned between a first processing chamber 100a and a second processing chamber 100b. In other embodiments, the gas reservoir may be positioned over the processing chambers 100. The gas reservoir 102 is positioned about 25 inches or less, 20 inches or less, 15 inches or less from the processing chambers 100. A gas panel 126 couples to the gas reservoir 102 with gas panel gas lines 122. The gas panel gas lines 122 can be any length operable to couple the gas panel 126 to the gas reservoir 102. For example, the gas panel gas lines 122 are about 80 inches to about 84 inches in length. The gas reservoir 102 couples to a plurality of valve blocks 104 with gas reservoir gas lines 120. The gas reservoir gas lines 120 are about 10 inches to about 15 inches in length. Each valve block 104 in the plurality of valve blocks 104 couples to a processing chamber 100 with valve block gas lines 124. The valve block gas lines 124 are about 5 inches to about 10 inches in length. The gas reservoir 102 can be fabricated from an aluminum material, a stainless steel material, or a combination thereof. The total distance from the gas reservoir 102 to a processing chamber (e.g., a first processing chamber 100a) is less than three feet.

The showerhead 118 may be coupled to an interior side of the lid 110. Gases (e.g., process and other gases) that enter the processing chambers 100 from the gas reservoir 102 pass through the valve block 104 and the showerhead 118 into the processing chambers 100. The showerhead 118 may be configured to provide a uniform flow of gases to the processing chambers 100. Uniform gas flow is desirable to promote uniform layer formation on the substrate 103. A plasma power source 160 may be coupled to the showerhead 118 to energize the gases through the showerhead 118 towards substrate 103 disposed on the substrate support assembly 138. The plasma power source 160 may provide RF power. Further, the plasma power source 160 can be configured to deliver power to the showerhead 118 at a variety of frequencies, such as a frequency between about 100 kHz and about 40 MHz. In some embodiments, the plasma power source 160 is configured to deliver power to the showerhead 118 at a high frequency radio frequency (HFRF) of 13.56 MHz.

The function of the processing chambers 100 can be controlled by a computing device 154. The computing device 154 may be one of any form of general purpose computer that can be used in an industrial setting for controlling various chambers and sub-processors. The computing device 154 includes a computer processor 156. The computing device 154 includes memory 158. The memory 158 may include any suitable memory, such as random access memory, read only memory, flash memory, hard disk, or any other form of digital storage, local or remote. The computing device 154 may include various support circuits 162, which may be coupled to the computer processor 156 for supporting the computer processor 156 in a conventional manner. Software routines, as required, may be stored in the memory or executed by a second computing device (not shown) that is remotely located.

The computing device 154 may further include one or more computer readable media (not shown). Computer readable media generally include any device, located either locally or remotely, which is capable of storing information that is retrievable by a computing device. Examples of computer readable media useable with embodiments of the present embodiments include solid state memory, floppy disks, internal or external hard drives, and optical memory (CDs, DVDs, BR-D, etc). In one embodiment, the memory 158 may be the computer readable media. Software routines may be stored on the computer readable media to be executed by the computing device.

The software routines, when executed, transform the general purpose computer into a specific process computer that controls the chamber operation so that a chamber process is performed. Alternatively, the software routines may be performed in hardware as an application specific integrated circuit or other type of hardware implementation, or a combination of software and hardware.

FIG. 2A is a schematic top view of a processing system 200 including a gas reservoir 102. FIG. 2B is a schematic perspective of a processing system 200 including a gas reservoir 102. The processing system 200 includes four processing chambers 100, a gas reservoir 102, a plurality of valve blocks 104, a gas panel 126, gas panel gas lines 122, gas reservoir gas lines 120, and valve block gas lines 124. However, in various embodiments, any number of processing chambers 100 may be implemented in processing system 200. Each of the gas lines (e.g., the gas panel gas lines 122, the gas reservoir gas lines 120, and the valve block gas lines 124) include a valve at the point of connection between components (e.g. the gas panel 126, the gas reservoir 102, the valve block 104, and the processing chamber 100). For example, there may be a valve to control flow between the gas panel 126 and the gas reservoir 102 along the gas panel gas line 122. The gas panel gas lines 122 connect the gas panel 126 to the gas reservoir 102. The gas panel 126 may be any distance away from the processing system 200. For example, the gas panel 126 may be a distance of 150 inches or less from the gas reservoir 102. Specifically, the distance between the gas panel 126 may be about 110 inches to about 130 inches away from the processing system 200. The gas reservoir 102 includes four compartments 111, each compartment 111 includes at least one valve (not pictured) to couple with a gas panel gas line 122. The gas reservoir gas lines 120 couple the gas reservoir 102 to the valve block 104 by coupling a gas reservoir gas line 120 to each compartment 111 of the gas reservoir 102. The valve block gas lines 124 couple the valve block 104 to the processing chamber 100. The gas lines (e.g., the gas panel gas lines 122, the gas reservoir gas lines 120, and the valve block gas lines 124) are configured to provide a faster flow of gas from the gas panel 126 to the processing chambers 100 due to the shorter distance from the gas reservoir 102 to the processing chamber 100.

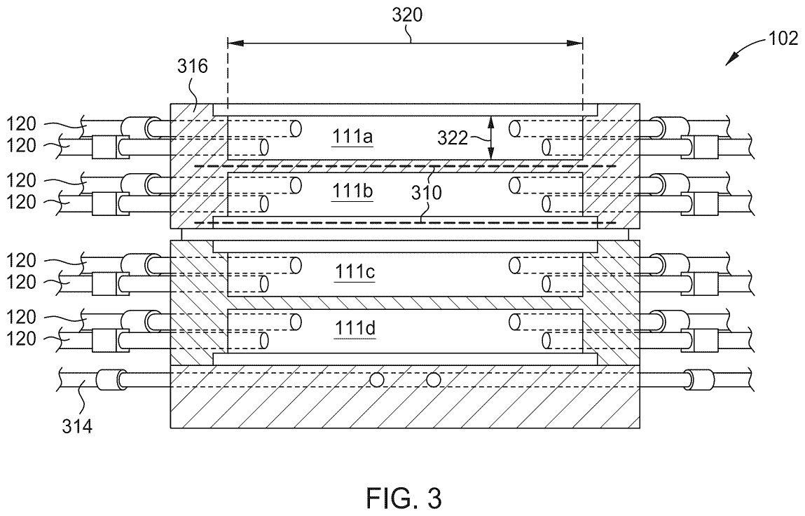

FIG. 3 is a schematic cross-sectional view of a gas reservoir 102. Gases (e.g., process and other gases) enter the gas reservoir 102 from a gas panel 126. The gas reservoir 102 includes four compartments 111 (e.g., a first compartment 111a, a second compartment 111b, a third compartment 111c, and a fourth compartment 111d). In other embodiments, the gas reservoir 102 may include more than four compartments 111 or less than four compartments 111. Each compartment 111 includes a first side 320 with a length and a second side 322 with a height. The aspect ratio between the first side 320 and the second side 322 is about 4:1. For example, in certain embodiments, a diameter of each compartment 111 may be 325 mm and a height of each compartment 111 may be 75 mm. Each compartment 111 can hold a different gas. For example, in certain embodiments, the first compartment 111a may hold a precursor gas (e.g., DIPAS (Di-Isopropylaminosilane) (S8)), the second compartment 111b may hold an inhibitor gas, the third compartment 111c may hold oxygen, and the fourth compartment 111d may hold argon. In other embodiments, multiple compartments may hold the same gas. Each compartment 111 may hold a volume of about 0.5 liters to about 5 liters, such as about 2 liters. In some embodiments, at least two compartments (e.g., the first compartment 111a and the second compartment 111b) are heated. The compartments 111 that are heated may include a heater cartridge 310 (as shown in FIG. 3) disposed within the wall 316 of the compartments 111, or the compartments that are heated may include a heated jacket. In some embodiments, all the compartments 111 are heated. The compartments 111 can be heated to a temperature of about 250 C. In embodiments that heat all the compartments 111, a heat box may be implemented to heat the entire gas reservoir 102. Heating the compartments (e.g., the first compartment 111a and the second compartment 111b) allows for vaporization of the gas held inside the compartments 111.

Each compartment 111 includes at least two valves coupled to gas lines (e.g., the gas panel gas lines 122, the gas reservoir gas lines 120). The gas lines (e.g., the gas panel gas lines 122, the gas reservoir gas lines 120) couple the gas reservoir 102 to the processing system 200. For example, the gas panel gas lines 122 couple the gas reservoir 102 to the gas panel 126. Each compartment 111 is coupled to at least one gas panel gas line 122. For example, the gas reservoir gas lines 120 can couple the gas reservoir 102 to the valve block 104. Each compartment 111 is coupled to at least one gas reservoir gas line 120. In some embodiments, the gas reservoir 102 couples to four processing chambers 100. In other embodiments, the gas reservoir 102 couples to two processing chambers 100. In certain embodiments, during operation, although the gas reservoir 102 is coupled to four processing chambers 100, not all processing chambers 100 may be active during processing. At least one splitter 314 is disposed under the compartments 111 within the gas reservoir 102. In some embodiments, there are two splitters 314 disposed under the compartments 111 within the gas reservoir 102. The splitter 314 allows for continuous gas flow from the gas panel 126, through the valve block 104, and to the processing chambers 100. Ar, N₂O, SiH₄, H₂, etchant gases, and combinations thereof may flow through the splitter 314 into the chamber.

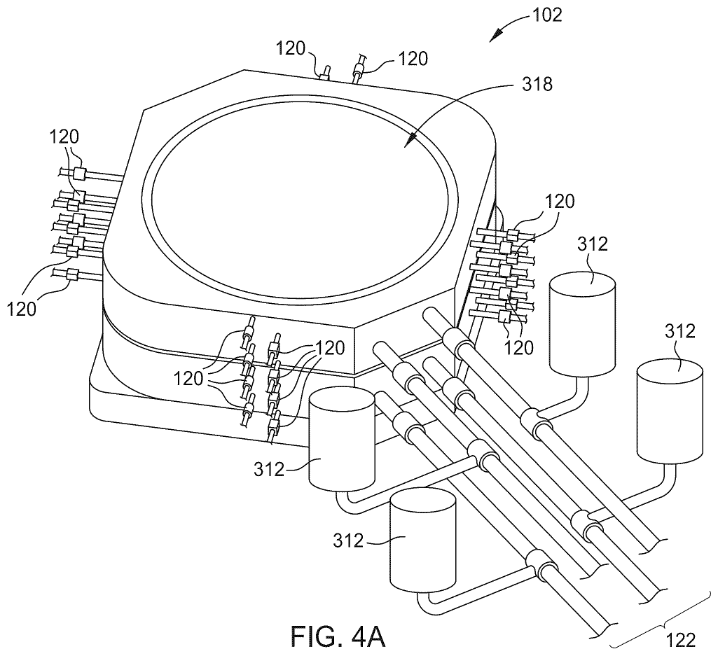

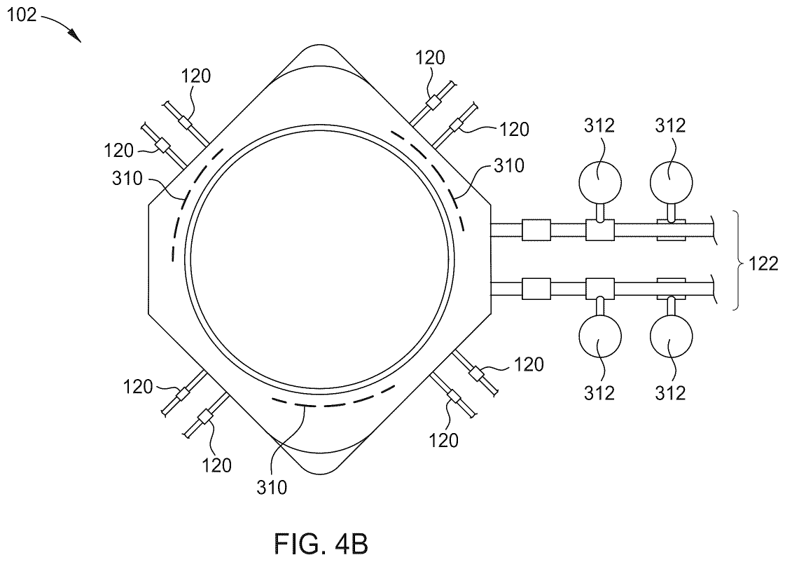

FIG. 4A is a schematic perspective view of a gas reservoir 102. FIG. 4B is a schematic top view of a gas reservoir 102. The gas reservoir 102 is coupled to at least one gas panel gas line 122. Each gas line of the gas panel gas line 122 includes a manometer 312 to monitor pressure in the processing system 200. The manometer 312 controls the pressure of each compartment 111 individually. The gas reservoir 102 is coupled to at least one gas reservoir gas line 120. As shown in FIG. 4A and FIG. 4B, the compartments 111 include a rounded shape 318. The rounded shape 318 and the high aspect ratio (as seen in FIG. 3) allows for uniform gas mixing and heating during processing. The rounded shape 318 and high aspect ratio also allows for the compartments 111 to easily stack on top of each other while maintaining the same footprint in the processing system 200.

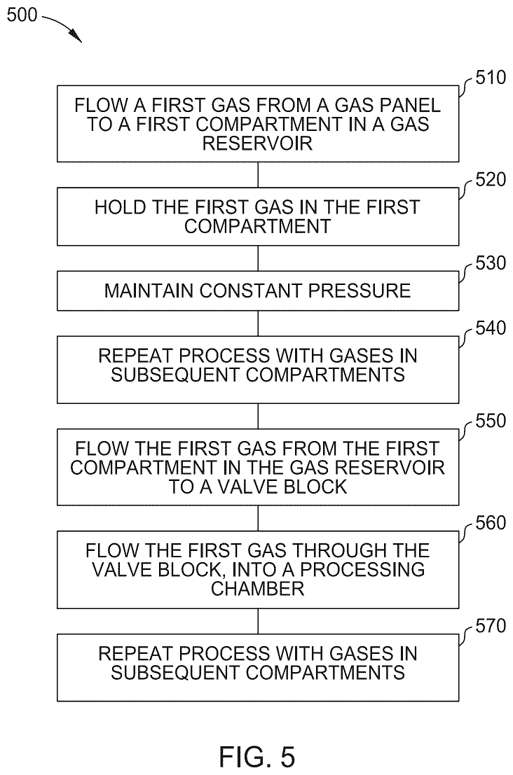

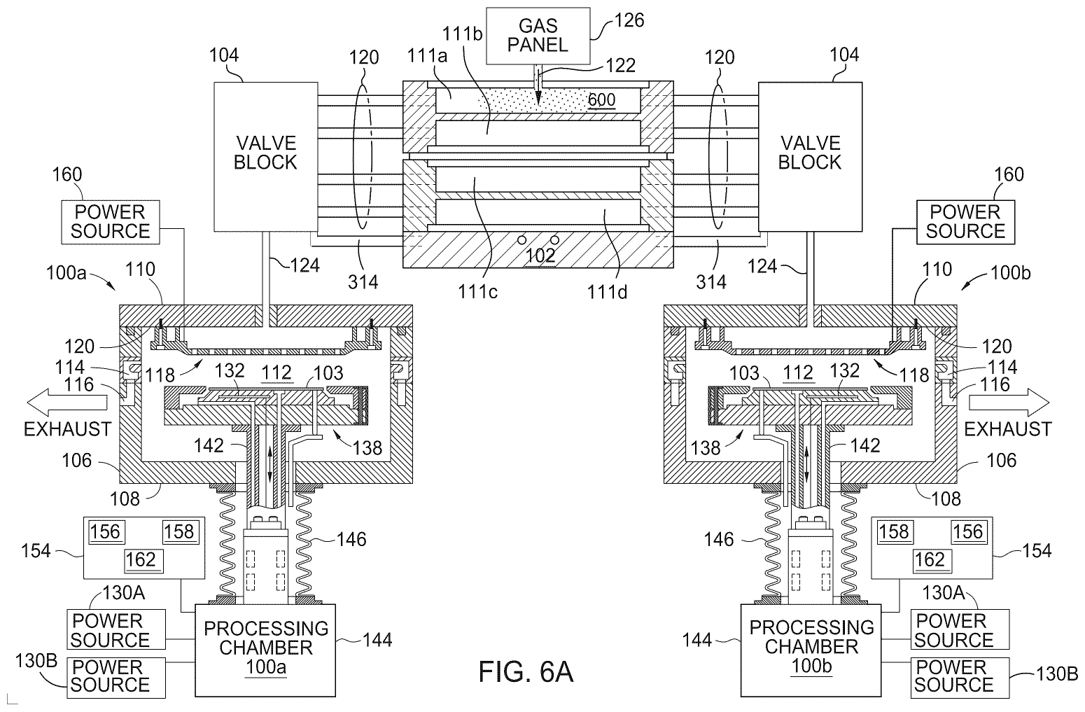

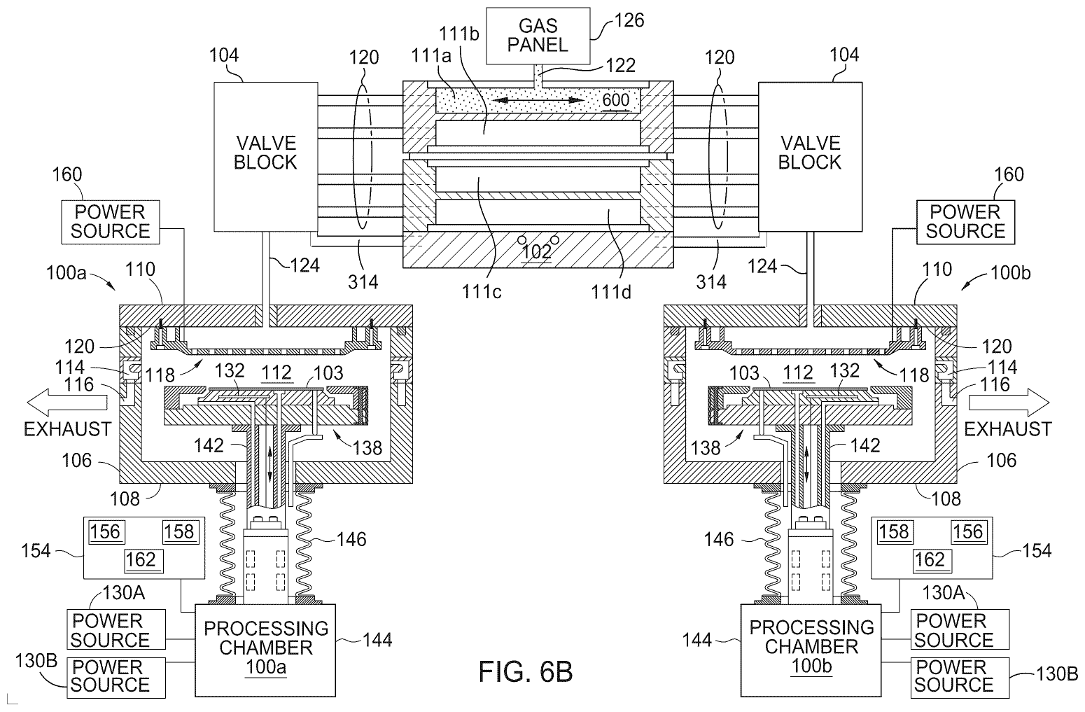

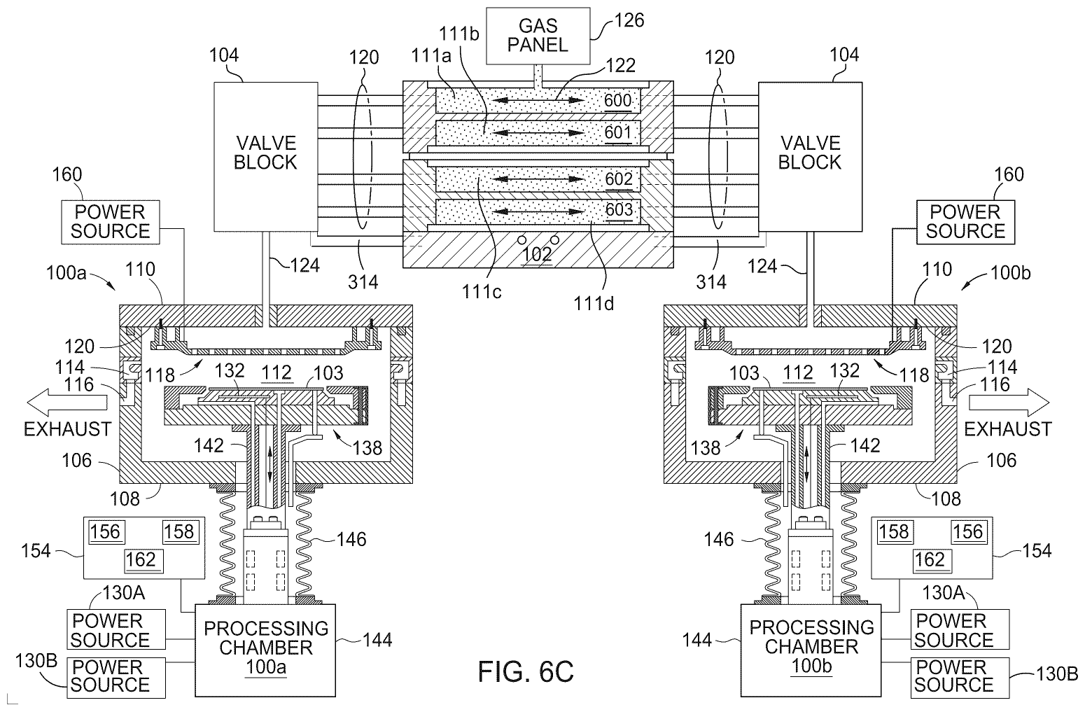

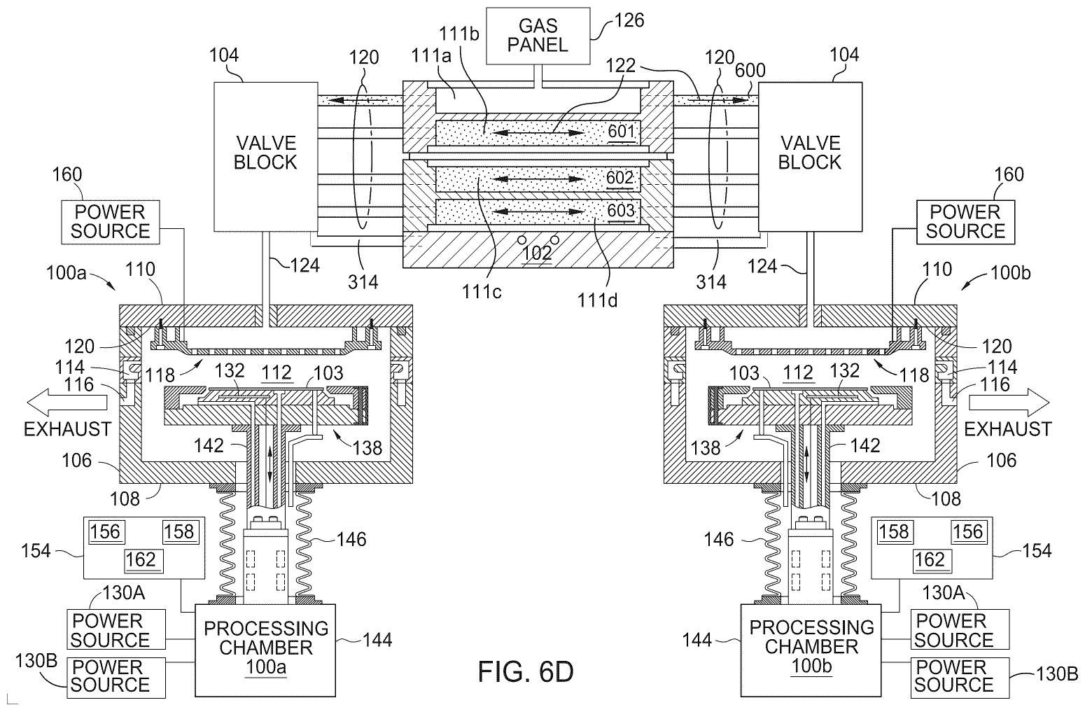

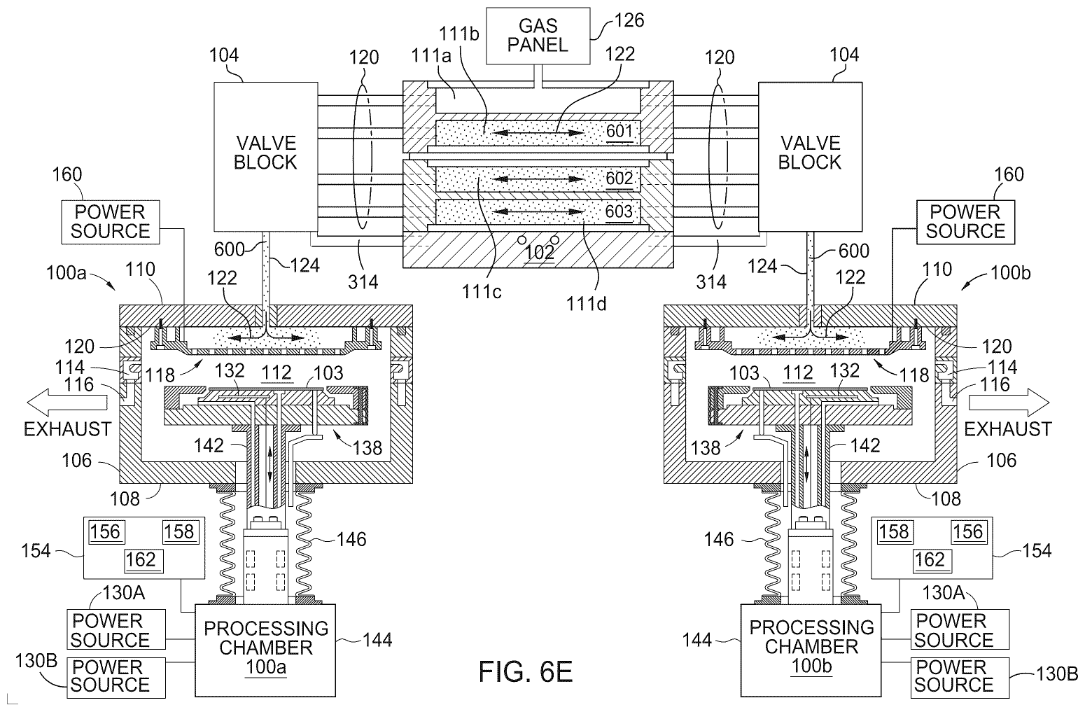

FIG. 5 is a schematic block diagram view of a processing system 200 during a substrate processing method 500. FIGS. 6A-6E are schematic diagrams of a processing system 200 during the substrate processing method 500. A first gas 600, a second gas 601, a third gas 602, and a fourth gas 603 are used as examples in the processing system 200. The gases may be process gases, reactive gases, carrier gases, purge gases, and/or any other gas required during semiconductor processing.

At operation 510, as shown in FIG. 6A, a first gas 600 is flowed from a gas panel 126 to a first compartment 111a in a gas reservoir 102. The gas panel 126 is coupled to the gas reservoir 102 by at least one gas panel gas line 122. In some embodiments, there is a gas panel gas line 122 coupled to each compartment 111 in the gas reservoir 102. For example, in certain embodiments there are four gas panel gas lines 122 and four compartments 111 in the gas reservoir 102. The gas panel 126 is positioned about 110 inches to about 130 inches from the processing system 200. Further, the gas panel gas line 122 is about 80 inches to about 84 inches. A manometer 312 is coupled to each gas panel gas line 122. The manometer 312 allows for independent closed loop control of the volume and the pressure in each compartment 111 in the gas reservoir 102. The control of the pressure in each compartment 111 allows for the rest of the processing system 200 to be unaffected by pressure changes in the gas reservoir. In other words, ongoing substrate processing continues without disturbance from pressure fluctuations. In other words, this allows for substrate processing to continue in the processing chamber while gas flows from the gas panel 126 into the gas reservoir 102.

A pulsing valve (not pictured) housed in the gas panel 126 assists in control of the pressure of the system based upon need of the desired processing method. Flow rate of each gas into the processing chamber 100 is determined by the pressure of the compartment 111 and the orifice (not pictured) in the valve block 104. A pressure of about 30 Torr to about 640 Torr is maintained in each compartment 111 for the gas held within the compartment 111. For example, the pressure may be maintained at or above 100 Torr, 150 Torr, 200 Torr, 250 Torr, 300 Torr, 350 Torr, 400 Torr, 450 Torr, 500 Torr, 550 Torr, 600 Torr, or 640 Torr. During processing the volume of the gas and the pressure of the compartment 111 may be reduced or increased according to processing needs without effecting the current processing step conducted in the chamber. In other words, the gas reservoir 102 can prepare gases by modulating the pressure of the compartments 111 for a next processing step or cycle while a current processing step or cycle in other portions of the processing system 200 (e.g., the valve block 104 or the processing chamber 100). For example, the processing chambers (e.g., first processing chamber 100a and second processing chamber 100b) may run a chemical vapor deposition (CVD) cycle while, at the same time, the gas reservoir 102 is filled with gases (e.g., a first gas 600 and a second gas 601) to conduct an atomic layer deposition (ALD) cycle directly after the CVD cycle. This allows for reduced processing times for a substrate processing method.

At operation 520, as shown in FIG. 6B, the first gas 600 is held in the first compartment 111a. Each compartment 111 may hold a volume of about 0.5 liters to about 5 liters, such as about 2 liters. The first gas 600 may be held in the first compartment 111a for as long as required by the processing method. At operation 530 a pressure fluctuations are controlled within the processing system 200. Pressure is measured and controlled by a manometer 312. Each compartment 111 acts as a capacitor for each gas (e.g., the first gas 600). Each compartment 111 is capable of maintaining a constant pressure and stopping flow of the gases (e.g., the first gas 600) enabling each compartment to hold the gases for an indefinite amount of time while processing continues in other portions of the processing system 200 (e.g., the valve block 104 or the processing chamber 100).

At operation 540, as shown in FIG. 6C, operation 510, operation 520, and operation 530 may be completed sequentially in the subsequent compartments. For example, a second gas 601 is flowed from a gas panel 126 to a second compartment 111b in a gas reservoir 102, a third gas 602 is flowed from a gas panel 126 to a third compartment 111c in a gas reservoir 102, and a fourth gas 603 is flowed from a gas panel 126 to a fourth compartment 111d in a gas reservoir 102. This process continues until multiple compartments 111 or all compartments 111 are filled with a gas. In some embodiments, each compartment 111 holds a different type of gas. In other embodiments, each compartment 111 may hold the same type of gas. In additional embodiments, some compartments 111 may remain empty during processing. The type of gas flowed into each compartment may change based on the substrate processing requirements. The gas panel 126 is positioned about 110 inches to about 130 inches from the gas reservoir 102. Further, the gas panel gas line 122 is about 80 inches to about 84 inches in length. Each gas (e.g., the first gas 600, the second gas 601, the third gas 602, and the fourth gas 603) is flowed from the gas panel 126 to a compartment 111. The filling of each compartment 111 is controlled by the desired pressure for each compartment 111. A pulsing valve (not pictured) housed in the gas panel 126 controls the pressure of the system based upon need of the desired processing method. Flow rate of each gas into the processing chamber 100 is determined by the pressure of the compartment 111 and the orifice (not pictured) in the valve block 104. A pressure of about 50 Torr to about 550 Torr is maintained in each compartment 111 for the gas held within the compartment 111.

In some embodiments, at least one splitter 314 is disposed within the gas reservoir 102 under the compartments 111. The splitter 314 supplies a constant flow of a gas from the gas panel 126 to the processing chambers 100. In some embodiments, at least one compartment 111 includes a heater cartridge 310 disposed within the wall 316 of the gas reservoir 102. The heater cartridge 310 controls the temperature of the compartment 111. Controlling the temperature allows for vaporization of gases (e.g., the first gas 600, the second gas 601, the third gas 602, and the fourth gas 603) if required.

At operation 550, as shown in FIG. 6D, the first gas 600 is flowed from the first compartment 111a in the gas reservoir 102 to a plurality of valve blocks 104 via gas reservoir gas lines 120. As shown in FIG. 6D, the first gas 600 is flowed to two valve blocks 104 simultaneously. In other embodiments, the first gas 600 is flowed to four valve blocks 104 simultaneously. The flow rate of the first gas 600 from the gas reservoir 102 to the valve block 104 is about 300 mgm to about 5000 mgm. An orifice (not shown) between the gas reservoir 102 and the valve block 104 controls the flow rate for the set pressure and allows for an even distribution of gases (e.g., the first gas 600, the second gas 601, the third gas 602, and the fourth gas 603) from the gas reservoir 102 to the processing chambers 100 based on processing needs. As the first gas 600 flows from the first compartment 111a, through the gas reservoir gas lines 120, to the valve block 104, the pressure in the processing system 200 fluctuates. The gas reservoir 102 allows for the pressure of the gases (e.g., the first gas 600, the second gas 601, the third gas 602, and the fourth gas 603) to be stabilized before flowing to the processing chamber 100. The pressure fluctuations within the processing system 200 is about 30 Torr to about 640 Torr. The processing system 200 includes a pressure switch that limits the maximum pressure to about 640 Torr. Controlling the pressure fluctuations within the processing system 200 allows for continuous, fast pulsing of a gas (e.g., the first gas 600, the second gas 601, the third gas 602, and the fourth gas 603) into the processing chamber 100 because there is less time spent stabilizing the pressure of the processing system 200 as the next gas moves through the processing system 200. The continuous, fast pulsing may be performed by pulsing the same gas (e.g., the first gas 600) repeatedly, or by pulsing different gases (e.g., the first gas 600, the second gas 601, the third gas 602, and/or the fourth gas 603) sequentially.

At operation 560, the first gas 600 is flowed from each valve block 104 to a processing chamber 100 via a valve block gas line 124. As shown in FIG. 6D, the first gas 600 is flowed to two processing chambers 100 (e.g., the first processing chamber 100a and the second processing chamber 100b) simultaneously. In other embodiments, the first gas 600 is flowed to four processing chambers 100 simultaneously. The flow rate from a valve block 104 to a processing chamber 100 is controlled by the pressure of the system. Each compartment 111 is coupled to each valve block in the plurality of valve blocks 104 via a gas reservoir gas line 120. A dose time is the time the gas (e.g., the first gas 600, the second gas 601, the third gas 602, and the fourth gas 603) flows from the valve block to the processing chamber 100. A dose time depends on the type of gas and which step is being performed in a substrate processing method. For example, for precursor saturation the dose time may be about 0.03 seconds to about 0.25 seconds on a blanket wafer. For example, for O₂ the dose time may be about 0.25 seconds to about 0.30 seconds based on desired treatment quality.

At operation 570, as shown in FIG. 6E, operation 550 and operation 560 are repeated for the second gas 601, the third gas 602 and the fourth gas 603. In some embodiments, the gases (e.g., the first gas 600, the second gas 601, the third gas 602, and the fourth gas 603) flow from their respective compartments 111 to the valve block 104 at the same time. Similar flow rates can be used for each of the gases (e.g., the first gas 600, the second gas 601, the third gas 602, and the fourth gas 603). In various embodiments, a dose time is the time the gas (e.g., the first gas 600, the second gas 601, the third gas 602, and the fourth gas 603) flows from the valve block to the processing chamber 100. A dose time depends on the type of gas and which step is being performed in a substrate processing method. For example, for precursor saturation the dose time may be about 0.03 seconds to about 0.25 seconds on a blanket wafer. For example, for O₂ the dose time may be about 0.25 seconds to about 0.30 seconds based on desired treatment quality.

After each gas (e.g., the first gas 600, the second gas 601, the third gas 602, and the fourth gas 603) enters the processing chamber, additional steps may be taken to deposit films on a substrate. The deposition processes may be performed via chemical vapor deposition (CVD) processes, physical vapor deposition (PVD) processes, atomic layer deposition (ALD) processes, PECVD processes, or any other suitable semiconductor processing technique. The processing system 200 is capable of conducting methods that include CVD cycles and ALD cycles.

Overall, various embodiments of the present disclosure provide devices and methods for storing and flowing processing gases into a processing chamber in order to perform deposition processes (e.g., CVD or ALD), inhibition processes, substrate treatments, etch processes or continuous etch processes. In particular, gases are stored in a gas reservoir before entering at least one processing chamber. The gas reservoir is positioned close to the processing chambers, allowing the pressure of gases to be more effectively stabilized during processing in the processing system. The close distance and the pressure stabilization allows for fast delivery of gases to processing chamber, which reduces the dose time. This reduction allows for fast switching between gases stored in the gas reservoir and fast pulsing of the same or different gases into the processing chamber from the gas reservoir. The fast switching and pulsing of the gases allows for reduced processing time. The reduction in processing time reduces processing delays, increases throughput of product, and reduces operational costs.

While the present disclosure has been described with respect to a number of embodiments and examples, those skilled in the art, having benefit of this disclosure, will appreciate that other embodiments can be devised which do not depart from the scope and spirit of the present disclosure.

What is claimed is:

1. A gas reservoir, comprising:
a first surface and a second surface, the first surface defining a length of the gas reservoir, and the second surface defining a height of the gas reservoir; a plurality of compartments, each compartment operable to hold a gas, and at least two compartments include heating capabilities;
a splitter disposed below the plurality of compartments, the splitter coupled to a gas panel and a valve block;
a plurality of gas panel gas lines; and
a plurality of gas reservoir gas lines.

2. The gas reservoir of claim 1, wherein the first surface and the second surface have an aspect ratio of about 4:1 or greater.

3. The gas reservoir of claim 1, wherein the gas reservoir includes four compartments.

4. The gas reservoir of claim 1, wherein each gas panel gas line of the plurality of gas panel gas lines is configured to flow a gas from the gas panel to one of the plurality of compartments.

5. The gas reservoir of claim 1, wherein each gas panel gas line of the plurality of gas panel gas lines includes a manometer.

6. The gas reservoir of claim 1, wherein each compartment of the plurality of compartments holds about 0.5 L to about 5 L of a gas.

7. The gas reservoir of claim 1, wherein the gas reservoir comprises aluminum, stainless steel, or a combination thereof.

8. A processing system, comprising:
a gas panel;
a gas reservoir, comprising:
a plurality of compartments, each compartment operable to hold a gas;
a plurality of gas panel gas lines; and
a plurality of gas reservoir gas lines;
a plurality of valve blocks, each valve block includes a plurality of valve block gas lines; and
a first processing chamber and a second processing chamber, wherein each of the first processing chamber and the second processing chamber is positioned about 24 inches or less from the gas panel, each of the first processing chamber and the second processing chamber comprising:
a processing volume at least partially defined by a chamber body;
a substrate support; and
an injector operable to inject the gas into the processing volume.

9. The processing system of claim 8, further comprising:
a third processing chamber and a fourth processing chamber, each of the third processing chamber and the fourth processing chamber comprising:
a processing volume at least partially defined by a chamber body;
a substrate support;
an injector operable to inject a gas into the processing volume; and
a plurality of valve block gas lines.

10. The processing system of claim 8, wherein each gas panel gas line of the plurality of gas panel gas lines is configured to flow a gas from the gas panel to the gas reservoir, and each gas panel gas line of the plurality of gas panel gas lines has a length of about 80 inches to about 84 inches.

11. The processing system of claim 8, wherein each gas reservoir gas line of the plurality of gas reservoir gas lines is configured to couple to at least one of the compartments of the plurality of compartments and to couple to at least one valve block of the plurality of valve blocks.

12. The processing system of claim 8, wherein each gas reservoir gas line of the plurality of gas reservoir gas lines has a length of about 10 inches to about 15 inches.

13. The processing system of claim 8, wherein each valve block gas line of the plurality of valve block gas lines is configured to couple to at least one valve block in the plurality of valve blocks and at least one processing chamber.

14. The processing system of claim 8, wherein each valve block gas line of the plurality of valve block gas lines has a length of about 5 inches to about 10 inches.

15. The processing system of claim 9, wherein the gas reservoir is positioned about 36 inches or less from the first processing chamber.

16. A method for using a gas reservoir in a processing system, comprising:
flowing a first gas from a gas panel to a first compartment of the gas reservoir, the gas reservoir including a plurality of compartments;
holding the first gas in the first compartment in the gas reservoir;
regulating a pressure of the first gas in the first compartment;
flowing the first gas from the first compartment in the gas reservoir to a plurality of valve blocks; and
flowing the first gas from the plurality of valve block to a plurality of processing chambers.

17. The method of claim 16, further comprising:
flowing a second gas into a second compartment of the gas reservoir;
flowing a third gas into a third compartment of the gas reservoir;
flowing a fourth gas into a fourth compartment of the gas reservoir;
holding the second gas, the third gas, and the fourth gas in the respective compartments;
regulating the pressure of the second gas, the pressure of the third gas, and the pressure the fourth gas;
flowing the second gas, the third gas, and the fourth gas from their respective compartments in the gas reservoir to the plurality of valve blocks; and
flowing the second gas, the third gas, and the fourth gas from the plurality of valve blocks to the plurality of processing chambers.

18. The method of claim 17, wherein the first gas, the second gas, the third gas and the fourth gas are different gases.

19. The method of claim 17, wherein the pressure of the first gas, the pressure of the second gas, the pressure of the third gas, and the pressure of the fourth gas are independently regulated in a closed loop control by a plurality of manometers, wherein each gas panel gas line of a plurality of gas panel gas lines includes a manometer.

20. The method of claim 17, wherein a substrate in a processing chamber of the plurality of processing chambers is processed during the flowing of the first gas, the flowing of the second gas, the flowing of the third gas, and/or the flowing of the fourth gas into the gas reservoir.
